(19) United States
(12) Patent Application Publication
(10) Pub. No.: US 2005/0166844 A1
(43) Pub. Date: Aug. 4, 2005

(54) High reflectivity atmospheric pressure furnace for preventing contamination of a work piece

(76) Inventor: Nicholas Gralenski, Aptos, CA (US)

Correspondence Address: MICHAEL HETHERINGTON, P.O. BOX 61047, PALO ALTO, CA, 94306, US

(21) Appl. No.: 10/772,188

(22) Filed: Feb. 3, 2004

(51) Int. Cl. C23C 16/00

(52) U.S. Cl. 118/724

(57) ABSTRACT

A furnace incorporating a novel thermal design is disclosed. Heating element temperature is reduced compared to conventional designs while providing a precisely controllable process temperature in the range 1000-1400 degrees centigrade. A plurality of Kanthal heating elements are arranged in a planar array as close to the work as possible, thus approximating an isothermal condition with respect to the work. The process chamber is made of aluminum and its internal surfaces are highly polished to reflect heat. The chamber walls have built in active cooling to carry away non-reflected heat and preserve high reflectivity. The heating elements are modular to facilitate removal and replacement without disassembly of the furnace. The configuration of the heating elements is linear rather than coiled and the temperature is monitored directly by measuring the electrical resistance of the Kanthal wires.

### CROSS-REFERENCE TO RELATED APPLICATION

This patent application claims the benefit of U.S. provisional patent application Ser. No. 60/445,562, filed Feb. 7, 2003, which is incorporated herein by reference.

### BACKGROUND

1. Field of the Invention

The field of the invention generally relates to a furnace for the formation of highly controlled, high purity films on a variety of substrates. In particular, the field of the invention relates to a high reflectivity furnace for chemical vapor deposition processes for the formation of source/drain junctions on a substrate at process temperatures reaching 1200° C. or more, at atmospheric pressure. The furnace achieves contamination-free heating of a work piece by using reflective heat containment rather than conventional thermal insulation and facilitates continuous processing with high throughput.

2. Background of Related Art

The manufacture of semiconductor devices requires the deposition of thin dielectric films upon semiconductor wafers at high working temperatures. The most commonly used process is chemical vapor deposition (CVD), using precursors such as silane, disilane, tetraethyl orthosilicate and others for the formation of a variety of films.

The manufacture of many devices requires the deposition of a variety of thin films on a variety of substrates. The most common is the preparation of microcircuitry on silicon wafer semiconductor substrates. Conductive, insulative, optical and dopant source coatings for later formation of source/ drain junctions are formed using a wide range of chemical processes.

Low temperature processes are preferred to avoid exaggerated diffusion effects. But high temperature processes are sometimes necessary to produce diffusion (e.g. dopants) in the first place, along with crystal formation and diffusion-purification effects. At high temperature, however, the list of suitable structural materials for a process chamber gets very small. And, even those with high temperature structural capacity, may be serious sources of contamination, or be unable to withstand the oxidation or other chemical conditions imposed. The materials list for a high temperature furnace or process chamber is therefore small and tends to get smaller as process specifications become more demanding.

Evaporation of metal can become a serious contamination factor in a conventional furnace for semiconductor processing, beginning at about 500° C. Such evaporation is a natural consequence of the vapor pressure of materials. Vapor pressure varies with materials and is about 100 billion times greater at 1200° C. than at 500° C. Yet, process conditions of 1200° C. and even higher are a focus of emerging interest.

As the need for thin film devices intensifies, so too does the need for a more efficient and economical furnace for device fabrication. Unfortunately, simultaneous improvement in fabrication processes, device performance and cost, has been difficult to achieve due to a number of structural and functional limitations in conventional furnaces. Conventional furnaces are often unsuitable for economical and high throughput thin film device fabrication, even for 500° C. processes, let alone operating ranges at 1200° C. and above.

In many furnaces for CVD, the process area and the product are isolated or separated from the heat source. Note that in such a furnace, the relationship between the heat source and the product is distant. More time is required for heating and cooling, and more heat source temperature is required to achieve the same product temperature. In other words, a larger temperature difference, ΔT, between heat source and product is required to induce heating of the work piece. Traditional thermal insulation generally is used to minimize heat loss and smooth out temperature gradients. But, this disadvantageously forces the process chamber to operate at high temperature and causes a slow rate of heating and cooling (poor thermal response) when a temperature change is required.

Therefore, what is needed is a furnace for CVD processing, especially at high temperatures, in which:
(1) the relationship of the heat source to product is optimized to avoid exceeding the physical limitations of the heat source; and
(2) unnecessary heating of the process apparatus is avoided because of material, structure, distortion, cost, contamination ,thermal efficiency and other problems.

Increasingly stringent requirements for processes are needed in order to produce quality thin film devices without impurities at reduced dimensions and at high production rates. And, conventional semiconductor processing systems are having more difficulty meeting these requirements. The materials for the process chamber are an important factor. The heat source and process chamber components are not acceptable if they are source of contamination.

Thus, in a conventional furnace, heating elements are typically located outside the process chamber. This means that the elements must now heat the process chamber, which in turn heats the work. This results in a disadvantageously large ΔT. Such a large ΔT means that the process chamber itself acts as a heat source hotter than the work. Accordingly, conventional process chamber materials are subject to drawbacks such as heat damage, distortion, may act as a source of contamination, entail time-consuming maintenance issues, are expensive, and slow down processing rates.

In a conventional substrate processing system, there is an aversion to the use of aluminum as a material for the walls in a high temperature process chamber due to its low melting point (660 degrees C.) and, in the case of a high temperature plasma, “due to physical sputtering of ions which attack chamber surfaces, such as aluminum walls, resulting in metal contamination of the substrate.” See U.S. Pat. No. 6,444,037 (emphasis added). However, as explained in further detail below, an aspect of the invention overcomes this presumed limitation and proves the opposite is true by removing as much heat as possible from the aluminum surface so that it remains relatively cool and thus inert with respect to the processing. Further, by polishing the aluminum to provide a mirror like surface, heat energy is thereby reflected back to heating elements, minimizing heat loss that would force the heating elements to a higher temperature for the same work temperature (thereby minimizing ΔT).

Another source of contamination in a conventional furnace for continuous CVD processing is the conveyor belt on which the substrate rests as it travels through various portions of the chamber for sequential processing. The conveyor belt typically comprises inconel alloy. At temperatures above 500° C., inconel itself becomes a source of evaporative metal contamination of the workpiece. Thus, what is needed is an improved furnace for CVD processing wherein all materials must be compatible with the process and the work product. CVD systems must be able to meet the higher demands for forming ultra-shallow doped regions including, source/drain junctions without evaporative metal contamination.

In conventional high throughput, thin film CVD processing, heating requirements are pushed to extreme limits. It thus becomes evident that in spite of the long history of furnaces, there is a great deal of room for improvement in the heating elements as well as in the design and construction of the process chamber. It is desirable for improved quality and purity of the thin film structures which produce source/drain junctions to achieve a process temperature of 1200° to 1300° C.; perhaps even 1350° C. For a workpiece to be heated to such temperature, the heating element itself must be even hotter. Materials that can survive such temperatures, are very few, fragile, very expensive, or limited to protective enclosures to prevent burnout or cannot survive exposure to required process atmospheres, or are themselves sources of contamination in the intended process.

With respect to heating elements, it is advantageous for the relationship between the heat source and product to be close (minimum ΔT). The thermal mass can be small, the thermal response much faster, and the means of control much improved. Most materials for heating elements are either too expensive or burn up too easily. Nickel chromium alloy (“Nichrome”) as a heating element takes advantage of chromium's tendency to quickly form chromium oxide (a highly stable ceramic) on the wire surface which then protects the remaining underlying metal. Nichrome wire is thus ductile, weldable, strong, has a desirable high electrical resistivity, and a reasonable service temperature of about 1200° C.

Another more recent alloy uses nickel and iron with a small percentage of aluminum. The aluminum melting point is low (660° C.) and thus not itself a high temperature material. However, it has a strong tendency to form aluminum oxide, a ceramic more stable and protective than chromium oxide. This material (“Kanthal”) has a service temperature of about 1400° C. The wire is ductile but becomes brittle as a result of excessive recrystallization at elevated temperature. Welding of Kanthal thus tends to produce a very fragile construction. The electrical resistivity of Kanthal is about 20% higher than Nichrome.

Wires can be made of higher temperature materials than Nichrome or Kanthal. Tungsten and molybdenum, for example, can have high surface temperatures exceeding 2000° C., but only under protected, oxygen free, and corrosive chemical free conditions. An ordinary light bulb, for instance, has a tungsten filament, actually a small heating element, operating typically at 2100° C. The filament is the light and heat source; the bulb provides the required protection. Such a bulb can be used as a heat source (e.g. heat lamp), but the bulb is often too fragile, and limits versatility in shaping the thermal structure.

The range of metallic materials used for electrical heat sources also can be used for a process chamber enclosure. Nickel chromium iron alloys such as stainless steel and inconel can be fabricated to intricate shapes and are much more durable than ceramic type materials. Semiconductors require a thermal process chamber where conditions can be very precisely maintained, but the process chamber must be fully compatible to process requirements. This is always more difficult as temperature gets higher.

For such a process chamber, the heat source, that is, the electrical heat element must obviously be the hottest component. As temperature rises, the first potential source for evaporative metal contamination must be the heat element. In addition, the processing conditions may involve gaseous chemicals which would be damaging to the heat elements.

Another problem in a conventional process chamber for semiconductor materials is that electrical connections through the wall of the process chamber may be a difficult and over-complicating structural feature. The heating elements are often placed outside the process chamber. Since this makes the heating elements more remote from the workload, it forces the elements to a higher temperature for the same product temperature. In a modem apparatus, the process chamber is a horizontal tunnel (muffle) through which product (such as silicon wafers) is carried on a wire mesh belt or conveyor.

The heating elements are typically all located outside the muffle. Such an arrangement is cost effective and production oriented, but it means that the heating elements may be operating at 1200° C., to heat the muffle to 750° C., which heats the belt to 650° C. which then heats the wafer to the desired temperature of 500° C.

The heat elements are within their reasonable surface temperature, but still the ΔT (element vs. wafer) is undesirably large, a consequence of the fact that the heating elements are remote from the silicon wafer. The situation is made more difficult by the fact that process gases flowing into the chamber tend to cause cooling, for which the heating elements can't compensate because they are too remote. The 500° C. example is a relatively low process temperature. A process temperature on the order of 1200° C. would be desirable, but this would put the elements well beyond their service limit. The process chamber and conveyor belt also would experience severe warpage, exaggerated oxidation and unacceptable metal evaporation and resulting workpiece contamination. Conventional furnaces for chemical vapor deposition (CVD) of silicon exhibit all of the foregoing disadvantages and undesirable features.

A factor that critically affects the throughput of a CVD process is the wafer temperature ramp rate. Such temperature ramping can be required at several points during a given process cycle. For example, a cold wafer must be heated to the appropriate treatment temperature. Also, the process may require different temperatures for different treatment steps. At the end of the process, the wafer ordinarily is cooled to a level that the wafer handling device can tolerate. The heating and cooling steps can represent a significant percentage of the processing time and can limit the reactor's throughput. The time between the steady state temperatures is essentially time which should be minimized to increase throughput.

The rate at which the wafer temperature can change from one steady state to another depends on the reactor's ramp rate. The reactor's ramp rate depends on the temperature controller type, temperature sensor, energy source, and other process considerations. A thermocouple is a device for measuring temperature in which a pair of wires of dissimilar metals (e.g., copper and iron) is joined and the wire's free ends are connected to an instrument (e.g., a voltmeter) that measures the difference in potential that is created at the junction of the two metals. When thermocouples are used to measure the wafer temperature, the thermocouple's thermal mass limits the response time to temperature changes. Thus, during a ramp, the thermocouple measurement significantly lags the wafer temperature. Reactors employing thermocouples are typically operated at ramp rates slower than the heating mechanisms can handle to limit the temperature difference between the wafer and thermocouple. If the ramp rate is too high, such that by the time the thermocouple temperature catches up to the wafer temperature, the wafer has been at a significantly higher temperature. Thus, the temperature controller reacts after the wafer temperature overshoots the target temperatures.

As a practical matter, a thermocouple cannot be attached to multiple wafers undergoing processing. Instead, a thermocouple is attached to a test wafer, and a periodic test must be run to determine process temperatures. However, this method is vulnerable to changing parameters during actual wafer processing.

Therefore, what is needed is a new furnace design wherein the temperature difference between the heating elements and the work is small (minimum ΔT). Then, the heating element temperature would provide an accurate measurement of work temperature.

What is also needed is an improved furnace design for CVD processing that places the heating elements in close proximity to a workpiece such that ΔT is minimized.

What is also needed is an improved furnace which can meet the increasing need to achieve consistent high yields in a CVD process for manufacturing semiconductor devices, at high working temperatures in a range from 1200° C.-1400° C. with precise process control. It also is desirable to provide new materials for a process chamber that can prevent contamination by metal evaporation at elevated temperatures, as vapor pressure of materials can increase 100 billion times from 500° C. to 1200° C.

### SUMMARY OF THE INVENTION

In order to overcome the foregoing disadvantages of conventional semiconductor processing systems, an aspect of the invention provides a thermal design that reduces heating element temperature, while providing a precisely controlled process temperature of 1200° to 1350° C. As set forth above, the heating element always must be hotter than the object being heated in order for heat to flow. But the temperature difference, or delta “T” (ΔT), can be greatly influenced by thermal design.

To achieve a minimal ΔT, an aspect of the invention disposes a plurality of heating elements in a planar array, and as close to the work as possible. The planar arrangement of the heating elements causes them to share the thermal workload. A second planar array of heating elements disposed beneath the work approximates an isothermal condition with respect to the work.

Another aspect of the invention overcomes the need to heat the process chamber. Instead, means are provided for bringing the heating elements into the process chamber.

In contrast to a conventional furnace, the internal surfaces of the process chamber are highly polished to reflect heat. At process temperatures mentioned, above 1200-1350° C., the dominant mode of heat transfer is radiation, which is then effectively contained by mirror surfaces. In other words, the process chamber is actually cold, but it looks hot. Since no mirror is perfect, some heat is absorbed which would begin to heat a polished process chamber. To counteract this effect, process chamber walls are made of a highly thermally conductive material (aluminum) with built-in active cooling to carry non-reflected heat away. This has been found to effectively compensate for the fact that, as mirrors rise in temperature, their ability to reflect heat decreases, even without damage to the polished surface. In other words, reflectivity decreases as temperature rises.

A further aspect of the invention uses aluminum as the material for the process chamber. Because aluminum melts at 660° C., it is not an obvious choice for the interior of a process chamber designed for process temperatures in the vicinity of 1200° C. and above. The aluminum walls forming the process chamber are polished to provide an “optical mirror” finish, characterized by very low emissivity (i.e. high reflectivity). It has been found that active cooling of the polished aluminum surface can be achieved by forced circulation of coolant (e.g. water) through channels disposed in or against exterior walls of the chamber or by circulating a gas (e.g. air) around cooling fins.

Aluminum also has the advantages of excellent thermal conductivity to facilitate uniform cooling, is economical in price, readily available, durable, adaptable to a wide range of mechanical structures, capable of being machined, formed, drilled and threaded as required and compatible with cooling and plumbing attachments

An aspect of the invention has found that it is not necessary for the process chamber itself to reach such elevated temperatures with all incumbent problems, in order to heat the workpiece. Instead, an important point of the invention is to bypass heating of the process chamber “box” to thereby avoid many other problems in a conventional furnace associated with the heating of the process chamber. In a conventional furnace, insulation (bricks, mineral wool, asbestos, etc.) is used for reducing heat loss. The thermal mechanism involves heating of such insulation. As the insulation gets hot, it radiates just like the heating elements do. This is similar to the mirror action. The mirror reflects heat back toward the heating elements, thus reducing the element temperature required to maintain the heating process. The heat insulation radiates heat back toward the heating elements, thus reducing the element temperature required to maintain the process.

Thermodynamically, reflection looks just like radiation. However, there is an important difference. For the insulation to radiate, it must become physically hot. That means heat is stored in the insulation. Time is required to store this heat. This means that the thermal response in a conventional insulated furnace is poor. Initial heat-up or cool-down or adjustment to a new process can take hours. This undesirably results in reduced ability to control temperature and thus dopant uniformity and junction depth of ultra-shallow doped regions formed in a conventional sequential CVD chamber; and is unsuitable for high throughput processing. In contrast, the heat reflector walls comprising the process chamber of the present invention are characterized by low thermal (zero) mass and do not store any heat. This advantageously enables rapid thermal response and high throughput.

Another aspect of the invention provides an improved heating element configuration comprising a plurality of Kanthal elements disposed within a ceramic sleeve. Multiple heating elements are then disposed in parallel across the process chamber. The heating elements are placed about three eighths inch (0.375) apart, which thermodynamically approaches a single continuous sheet of hot surface. If one such sheet is disposed above the work being processed, and a second sheet below, the work is exposed to a good approximation of an isothermal chamber; the work being surrounded by a hot (element) surface with reflective heat containment.

The heating element terminal structure is designed so that the heating elements are modular for ease of removal without disassembly of the furnace. When a heating element is installed through an access port in a terminal panel, an electric terminal covers the access port. The terminal panel thus forms a secondary chamber along side the process chamber. The terminal chamber is purged with inert gas (such as argon). Thermal oxidation of heating elements is advantageously suppressed or eliminated by argon. Such purging action also implies that high temperature, oxidation sensitive material like molybdenum, can be considered for heating element service. The argon is also circulated through the terminal chamber to keep it oxygen free, such that heating elements are exposed to an inert atmosphere inside the walls of the terminal chamber. Thus, the heating elements are kept in an oxygen free atmosphere that prevents oxidation.

The configuration of the heating elements is linear, providing a consistent relationship of watts per linear inch. This enables temperature to be determined directly by monitoring the electrical resistance of the Kanthal within the ceramic sleeve. This method tracks the temperature within the heating elements and thus provides an accurate, substantially instantaneous measurement of temperature within the heating element, without the time lag of a conventional thermocouple. Active feedback of temperature is provided to a temperature controller to ensure a quick thermal response when desired.

Yet another aspect of the invention provides sequential processing of a semiconductor substrate without the need for a conveyor belt. A rail is provided on the walls of the process chamber to enable substrates to slide in one end, continuously, for thermal processing steps and exit the other end. Alternatively, a quartz plate or equivalent structure capable of withstanding elevated temperatures without warping can be used to slideably transport a substrate through the furnace without the need for a conveyor belt.

A further aspect enables surface coatings of higher purity to be deposited on a substrate due to the 1200° C. process temperature achieved by the invention. This can upgrade the performance of the substrate in terms of optical qualities, wear characteristics or electrical qualities. For example, an aspect of the invention enables a surface layer of silicon to be deposited under conditions that provide substantially higher purity with respect to a silicon substrate. The high temperature process makes the deposited silicon more crystalline, but the crystals orient themselves with respect to the structure of the underlying crystals in the substrate. This has particular application to the cost effective production of solar cells. Also, formerly cost sensitive PN junctions for photovoltaic devices now can be produced economically with high throughput.

### BRIEF DESCRIPTION OF THE DRAWINGS

These and other features, aspects and advantages of the invention will become better understood with regard to the following descriptions, appended claims and accompanying drawings in which:

FIG. 1 is a perspective drawing of the furnace in accordance with an aspect of the present invention.

FIG. 2 is an enlarged perspective drawing of the furnace and process chamber in accordance with an aspect of the present invention.

FIG. 3 is a front view of the furnace and process chamber in accordance with an aspect of the present invention.

FIG. 4 is a close up side view of an access port for receiving heating elements into the process chamber

FIG. 5 is a perspective front view of a furnace and process chamber in accordance with an aspect of the present invention.

FIG. 6 is an enlarged perspective front view of FIG. 5 in accordance with an aspect of the present invention.

FIG. 7 is a perspective view of a heating element in accordance with an aspect of the present invention.

FIG. 8A is a diagrammatic side view showing sections of a heating element in accordance with an aspect of the present invention.

FIG. 8B is a diagrammatic side view of a heating element in accordance with an aspect of the invention.

FIG. 9 is a sectional view of a heating element in accordance with an aspect of the invention.

FIG. 10 is a perspective view of a heating element and torque limiting apparatus in accordance with an aspect of the invention.

FIG. 11 is a perspective side view of a furnace and gas purge apparatus in accordance with an aspect of the invention.

FIG. 12 is a perspective side view of furnace and terminal chamber including cooling fin bus bars in accordance with an aspect of the invention.

FIG. 13 is a generalized circuit diagram for determining temperature as a direct function of the resistance of the linear heating elements in accordance with an aspect of the invention.

### DETAILED DESCRIPTION

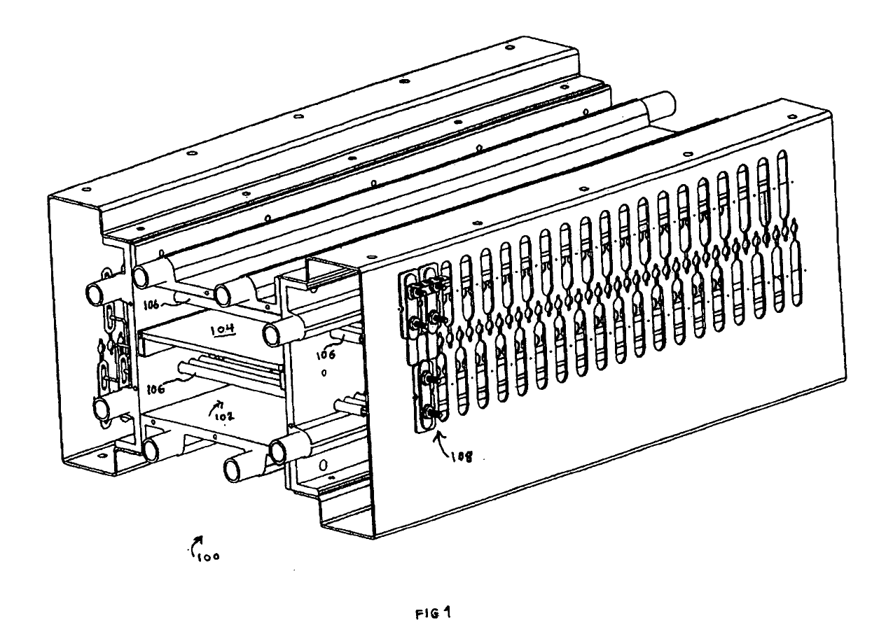

Reducing Source Temperature Required To Heat A Workpiece Referring to FIGS. 1, 2 and 3, a furnace 100 is provided that includes a process chamber 102 for accepting a workpiece 104, typically a semiconductor substrate, for processing. A plurality of heating elements 106 are disposed in first and second substantially parallel banks or arrays, above and beneath work piece for evenly heating the workpiece. The heating elements have a threaded terminal end 108 disposed in a ceramic spacer and insulator 110 that is conformably received in an aperture 112 in a side wall surface 114 for holding the distal ends of heating elements. The threaded end includes an attachment means, such as a locking nut 116 for attaching a lead to a source of electric power.

Referring to FIG. 1, an objective of the invention is to minimize the above described problems of conventional furnaces by identifying a thermal design that would reduce the heating element temperature. As mentioned, the heating element always must be hotter than the object being heated in order for heat to flow. In FIG. 1, the heating elements 106 are at temperature T1. The workpiece 104 is at temperature T2. T1 must always be greater than T2. Thus, T1−T2=T. But the temperature difference, or delta “T” (ΔT), can be greatly influenced by thermal design. To achieve a minimal ΔT, the heating elements must be placed as close to the work as possible. In many instances, such intention is frustrated by the need to place the work in a process chamber, which contains a vacuum or highly purified gases required for a CVD process. Attempting to thread electrical wires, connectors and heating elements into the chamber would unsatisfactorily compromise the chamber's ability to protect the process. Thus, in a conventional furnace, heating elements are typically outside the process chamber. This means that the elements must now heat the process chamber, which now heats the work. This results in a disadvantageously large ΔT. Such a large ΔT means that the process chamber itself acts as a heat source hotter than the work.

Conventional process chamber materials are subject to drawbacks such as heat damage, distortion, may act as a source of contamination, entail time-consuming maintenance issues, are expensive, and slow down processing rates.

Overcoming The Need To Heat The Process Chamber

An aspect of the invention provides a means for bringing the heat elements 106 into the process chamber 102 which bypasses the above damage to, or damage caused by conventional heating of the process chamber. That is, according to this aspect of the invention, the process chamber no longer needs to be heated. Of course, a cold chamber would now be a source of heat loss, disrupting process temperature control, and forcing the heating elements to work harder; i.e. achieve higher temperature to make up for such heat loss. The heat loss could be minimized by using thermal insulation. But all such insulation is dusty, crumbly, and porous, factors which would severely interfere with process control.

Containing Heat with Polished Surfaces

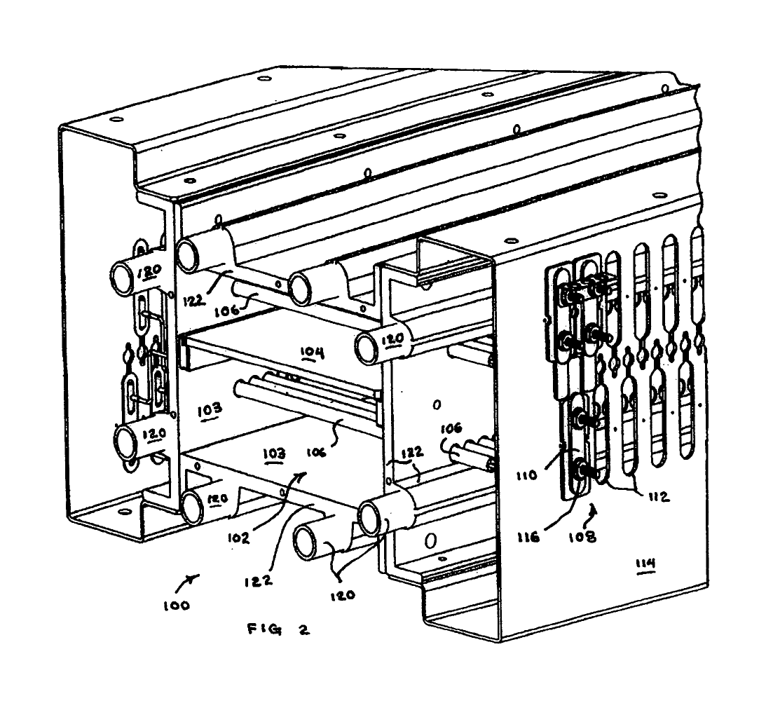

Referring to FIG. 2, in contrast to a conventional furnace, in an aspect of the invention, the internal surfaces 103 of the process chamber 102 are highly polished to reflect heat. The polishing process maintains asperities below about 5 microns. At the process temperatures mentioned, above 1000° C., the dominant mode of heat transfer is radiation, which is then effectively contained by mirror surfaces. In other words, the process chamber is actually cold, but it looks hot. The physics of radiant heat transfer are such that it is not possible (by looking) to tell the difference between a hot radiator and a brilliant hot looking reflector. Of course, that is the case for a perfect mirror. Since no mirror is perfect, some heat is absorbed which would begin to heat a polished process chamber.

Cooled Polished Surfaces

To counteract this effect, a process chamber 102 is made of a highly thermally conductive material, aluminum, with built-in cooling channels 120 to carry non-reflected heat away. In a preferred embodiment, cooling channels 120 comprise copper pipes conformably held in aluminum extrusions 122 which are integral with external surfaces of the walls of process chamber 102. Preferably, a silicone heat sink compound (grease) mixed with zinc oxide powder is used to coat the copper tubing to provide a more efficient transfer of heat out of the process chamber walls 103. The heat sink compound forms a liquid interface between the cooling channels and the process chamber walls. It eliminates air gaps and provides more efficient heat transfer.

Alternatively, one can make the aluminum extrusions so that they form an enclosed channel or bore integral with the walls 103 of the process chamber 102.

Referring again to FIG. 2, the interior walls 103 of process chamber 102 are highly polished to provide a mirror surface. A consideration for good thermal design is that as mirrors rise in temperature, their ability to reflect heat decreases, even without damage to the polished surface. In other words, reflectivity decreases as temperature rises. If the mirror becomes too hot, the polished surface is likely to become permanently damaged, further decreasing reflectivity.

Mirrors can be made so the heat facing side is highly polished and the backside black. Such an arrangement minimizes hot side absorption while the black side facilitates radiant loss of that heat fraction which is absorbed. However, the mirror temperature still must rise undesirably, because even black body radiation is too small at low temperature to dissipate absorbed heat.

Liquid And/Or Gas Cooling

Thus, the best way to cool the polished surface is by active cooling through liquid channels (e.g. water) or gas cooling fins (e.g. air). Thus, in an alternate embodiment, aluminum extrusions can be provided on exterior surfaces of process chamber walls to aid in removing heat.

Aluminum As A Material Choice

A problem arises in finding “a mirror” which is economical in price, readily available, durable, adaptable to a wide range of mechanical structures, capable of being machined, formed, drilled and threaded as required and compatible with cooling and plumbing attachments. Aluminum meets the foregoing requirements, has excellent thermal conductivity to facilitate uniform cooling, and optically can be polished to a very low emissivity (i.e. high reflectivity). This is the reason that aluminum, and not Chromium, stainless steel, or even gold, is used in the most demanding of optical applications (such as the Hubble Orbiting Telescope). Aluminum is further amenable to extrusion techniques which make it readily available in myriad shapes to facilitate structures and cooling. An advantage of gold or other precious metal is corrosion resistance. If corrosive conditions attack polished aluminum, gold plating of aluminum can be a useful alternative.

Because aluminum melts at 660° C., it is not an obvious choice for the interior of a process chamber designed for process temperatures in a range of 1250° C. and above. Prototype furnaces have been made according to the invention and have achieved 1250° C. process temperatures even though the furnace is made of a material which melts at 660° C. Moreover, the exterior surface temperature of the prototype furnaces only reaches about 35° C.

Workpiece Temperature And Process Chamber Temperature No Longer Related

An aspect of the invention provides that it is not necessary for the process chamber itself to reach such elevated temperatures, with all incumbent problems, in order to heat the workpiece. Instead, an important point of the invention is to bypass problems which come with the heating of the process chamber.

In a conventional furnace, insulation, bricks, mineral wool, asbestos, etc. are used for reducing heat loss. The thermal mechanism involves heating of such insulation. As the insulation gets hot, it radiates just like the heating elements do. This is similar to the mirror action. The mirror reflects heat back toward the heating elements, thus reducing the element temperature required to maintain the heating process. The heat insulation radiates heat back toward the heating elements, thus reducing the element temperature required to maintain the process.

Zero Thermal Mass Of Reflectors Provides Rapid Thermal Response

Thermodynamically, reflection looks just like radiation. However, there is an important difference. For the insulation to radiate, it must become physically hot. That means heat is stored in the insulation. Time is required to store this heat. This means that the thermal response in a conventional insulated furnace is poor. Once reached, temperature stability of a conventional insulated system can be very good. But initial heat-up or cool-down or adjustment to a new process can take hours. Heat reflectors, by comparison, are characterized by low thermal (zero) mass and do not store any heat. This advantageously enables rapid thermal response on the order of minutes.

Means for Minimizing Convection

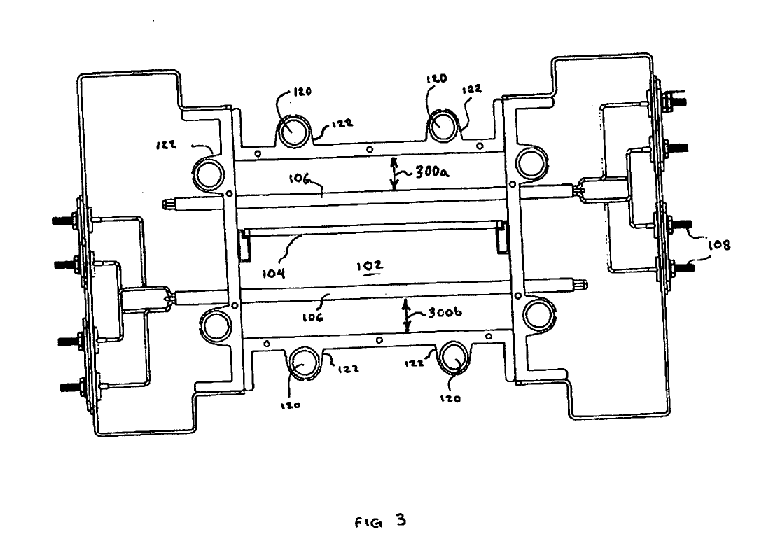

Another mode of heat loss which could force a higher ΔT is convection. That is, the circulation of gases in the process chamber carrying heat from hot surfaces to cold surfaces. Convection is a “chimney effect” inducing upward cooling flows induced by hotter, lighter gases carrying lost energy with them. Referring to FIG. 3, in an aspect of the present invention, vertical dimensions at 300a and 300b of the process chamber 102 are kept small in order to restrict the chimney effect and many of the heating elements 106 are located near the top of the process chamber 102 because convection cannot work from the top down.

Minimizing Conduction At Contact Points

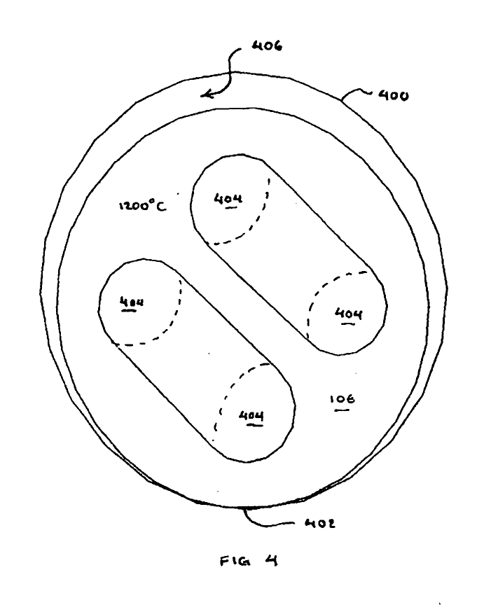

Referring to FIG. 4, the only other mode of heat loss is conduction. Conduction through a stagnant gas is very small, essentially negligible. Conduction at points of hot to cold contact can also be small if the contact point area is small. The heating elements 106, are ceramic sleeves, cartridge-like in design, and are slipped through slightly larger access holes or ports 400 provided in the polished aluminum extrusions which form the walls 103 of the process chamber 102. Kanthal heating element wires 404 are disposed within the ceramic sleeve as will be explained. A clearance space 406 is provided to minimize heat transfer from heating element 106 into the aluminum surface of access port 400. The heating elements 106, operating at about 1200° C., are in actual contact with the aluminum at the bottom of the access hole 400. The contact point 402 is a minimized tangential point. The contact is virtually 2 point (zero cross sectional area) and there is little indication of heat loss (which would make the heat elements cool and the aluminum hot) in spite of such a large temperature.

Maximizing Conduction At Contact Points

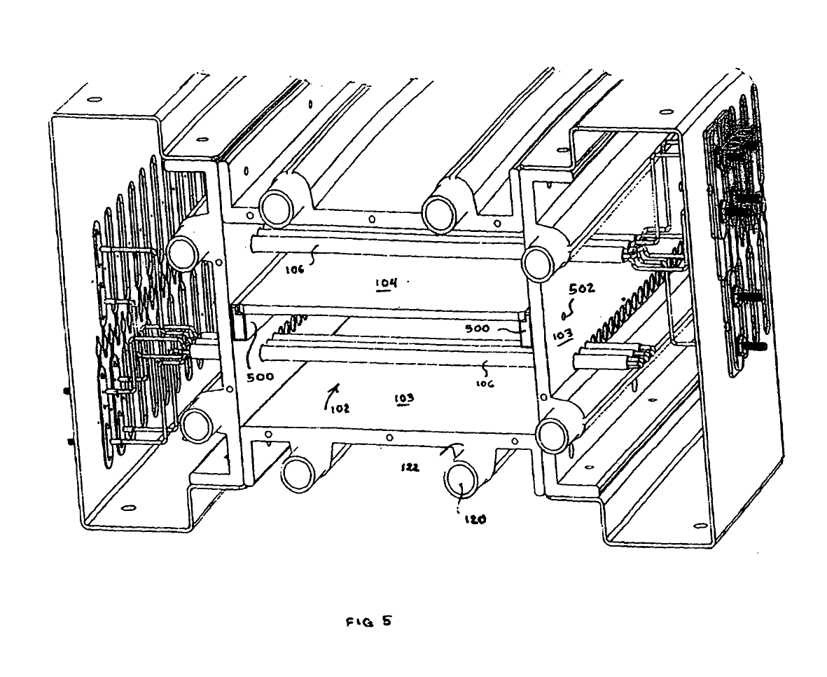

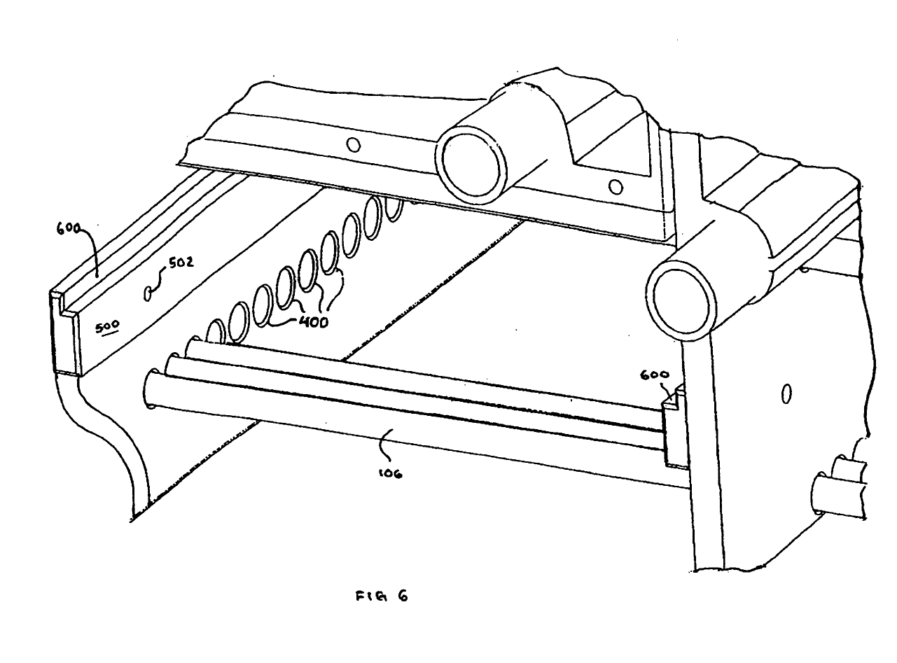

Referring to FIGS. 5 and 6, there is another area in the present design where the reverse effect is used to advantage. The furnace is intended for horizontal processing; that is, substrates or carriers of some kind, slide in one end of the process chamber 102, continuously, for thermal processing and come out the other end. A rail 500 is thus required in the furnace hot region for such sliding to occur. In one embodiment rail 500 is made out of aluminum. It is fastened to the polished interior surface 103 of the process chamber 102 with small screws 502. These small screws support the rail 500 but also pull it close to the cooled aluminum process chamber walls 103. This close contact with the cooled walls thus cools the rail as well.

The rail 500 is polished to minimize heat absorption and cooled through the action of the support screws 502. Referring to FIG. 6, notch 600 is provided in the rail 500 where the slide action with a workpiece 104 or carrier, such as a quartz plate occurs. Notch 600 is hard anodized (i.e. aluminum oxide hard surface). The hard anodizing is somewhat rough, meaning the points of contact between the rail and workpiece or carrier are small, which minimizes heat transfer. A workpieces or substrates are thus supported, with minimal cooling, while the rail has minimal heat loading to deal with. The hard anodizing helps reduce heat loss in spite of a sharp thermal gradient, while providing a wear resistant sliding surface.

Other Rail Concepts

There are other rail concepts which may work effectively, and even have advantages. Examples include making the rail structure out of a refractory metal, such as molybdenum, which can readily handle such temperature, provided the process atmosphere is not oxidizing or otherwise corrosive. The surface of the molybdenum can be treated with materials such as silicon or carbon to increase its resistance to chemical attack. The substrates may also roll on small ceramic balls moving in grooves formed on the rails or on a grooved feature of aluminum extrusion which has no separate attached rails.

The invention description thus far has been mostly related to design concepts which enable reduction of ΔT (actual element temperature minus work temperature). A sufficiently small ΔT improves the chance that conventional heating element material (such as one of the Kanthal series) may be up to the task. A practical service limit for Kanthal is 1400° C. Thus, if a ΔT of 100° C. can be achieved, then a work process temperature of 1300° C. can also be achieved. However, in industry it is evident that a ΔT of many hundreds, even 1000° C. may be required. From prototype apparatus relating to this invention, it appears that the ΔT achieved is less than 200° C., thus providing capability for the use of Kanthal.

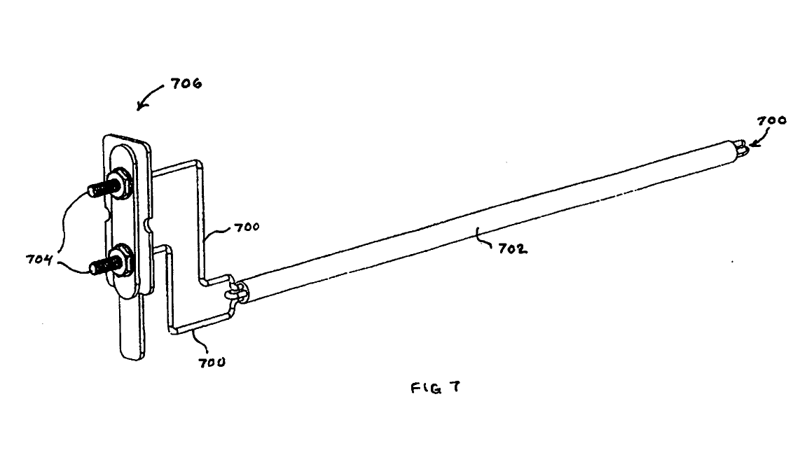

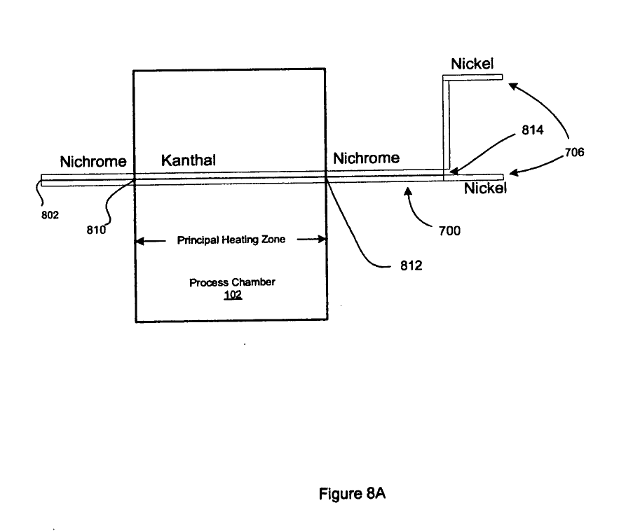

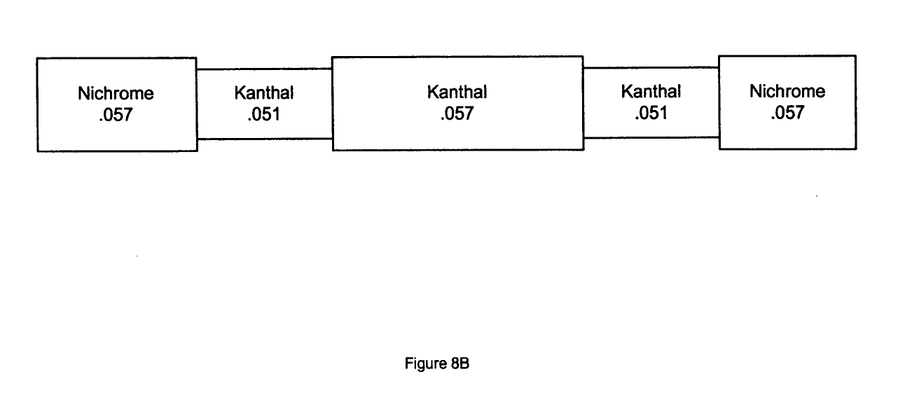

Referring to FIGS. 7 and 8, actual determination of the heating element temperature is difficult because heating element wires 700 are hidden in a supportive ceramic tube 702. It is primarily the absence of chronic failures of heating elements which provides the capability of using Kanthal rather than actual element temperature. If the Kanthal cannot be used, the other candidate choices are all much more difficult and expensive to work with. While these more difficult and expensive elements could be utilized, it appears the Kanthal elements are suitable for a process temperature of at least 1200° C., and that 1200° C. may also be suitable for the process(es) required.

As mentioned near the beginning text, the design concept is to place the heating elements as close to the work as possible. However, at this operating temperature, the Kanthal metal would be a serious evaporative contamination risk to the substrates being processed. Referring to FIGS. 7 and 8, there are many other design factors for the heating elements as well, such as:

1. Convenient Installation

Heating elements in many commercial furnaces are prohibitively difficult to replace. The implication is that if the element operates at a modest temperature its life will be long. The expectation in this case is one of pushing the limit; failure may be more likely (because of the high temperature service), but tolerable, if replacement is easy and practical.

2. Means Of Power Distribution

The operating temperature of an element varies with input power and also with heat loss. The end of a heating element may operate cooler, for example, than the interior because of increased heat loss. If the element design can enable increased resistive heating in this area, the compensation makes temperature and process more uniform. The electrical terminals 704 themselves have to be one such “end” to the elements. But here the temperature must be kept low to avoid destruction of the electrical connection. Lowering resistive heating in this area reduces risk of terminal damage.

3. Coiling

Heating elements are more durable when made of larger wire, but then circuit resistance is low. This means the power supply must be oriented to high current and low voltage, an undesirable combination. To off-set this effect, the wire is often coiled. Coiling increases the length of wire between terminals and increases resistance in proportion. There is often the perception that this larger amount of wire can handle proportionally larger amount of power (wattage). It is visibly evident that coiled wire heats more readily. But what is actually happening is that when each coil heats it has a strong tendency to also heat adjacent coils. The coiled wire gets hot more readily, but that's because the heat energy can't escape as readily. The heat has to escape in order to heat the work.

The heating element has to get hot, but its purpose is to heat the work. These are really separate concepts. Coiling thus works to increase ΔT. For low temperature applications, coiling can be effective. For high temperature applications, coiling may push the element wire beyond its limits.

Another aspect of coiling is that if the coils are not kept accurately spaced (they usually aren't), closer spacing produces hot spots (element failure) and wider spaces produce cold spots (process temperature non-uniformity).

Referring to FIG. 8, one of the mechanisms at work here is that as wire heats up to high temperature it undergoes substantial thermal expansion. It must move or squirm to accommodate length change. Squirming distorts the element geometry and can be a factor in coil spacing. Thus, an aspect of the invention allows free thermal expansion motion, retains intended geometry and avoids stressing of the hot, weak element wire.

4. Heating Element Density

Referring to FIG. 6, for high temperature service, a large number of elements working together will reduce the risk that the elements may reach or exceed their maximum service temperature. As the number of elements increases, the ΔT decreases. The ultimate configuration would be on wherein the work is 100% enclosed in a hot surface while the hot surface is surrounded by another enclosure which prevents any heat from escaping. Such a configuration is impossible, but an element design which allows close approximation is very advantageous. In an aspect of the invention, the ability to dispose a relatively dense planar array of heating elements above and below the work and in close proximity to a workpiece, in combination with the highly reflective walls of the process chamber, provides a substantially isothermal chamber with respect to the workpiece where the ΔT is a minimum.

5. Electrical Insulation

Referring to FIGS. 7, 8A and 8B, electrically powered heat elements will obviously need some type of insulation to prevent closely spaced wires from shorting together or short-circuiting to conductive parts of a furnace structure. At high temperature, however, this insulation must be very carefully chosen. Even high temperature materials like quartz and ceramic are not necessarily adequate.

The presently available heating element material, Kanthal, is a metallic alloy made of nickel, iron and a few percent aluminum. For high temperature service, this alloy, by its nature, forms a surface layer of aluminum oxide. This oxide is a form of corrosion which then becomes highly protective to the remaining underlying metal. Aluminum oxide (in pure crystalline form, sapphire) is one of the most durable of ceramics. It is this nature of Kanthal which makes it a prime high temperature element material.

Any contamination of this surface oxide is likely to degrade its performance. Any insulator in contact with the hot wire would have to be a contamination suspect unless it also is high-grade aluminum oxide. Thus, alumina ceramic emerges as the preferred high temperature insulator, because of its compatibility with Kanthal.

There are other potential element materials besides Kanthal. Their advantages, disadvantages, material and design requirements could be considered just as with the Kanthal/alumina system.

6. Element Structural Support

The melting point of Kanthal is 1500° C. Maximum practical service temperature is 1400° C. The expected service requirement is 1400° C. (for a work temperature of 1200-1300° C.). At this temperature, Kanthal's mechanical strength is very weak (the term “wet noodle” is applicable). Alumina ceramic, by comparison melts at 2050° C. and its strength at 1400° C. is excellent.

Ceramic tubing 702 with element wire 700 threaded therethrough thus emerges as an attractive element structural configuration.

7.Element/Ceramic Heat Transfer

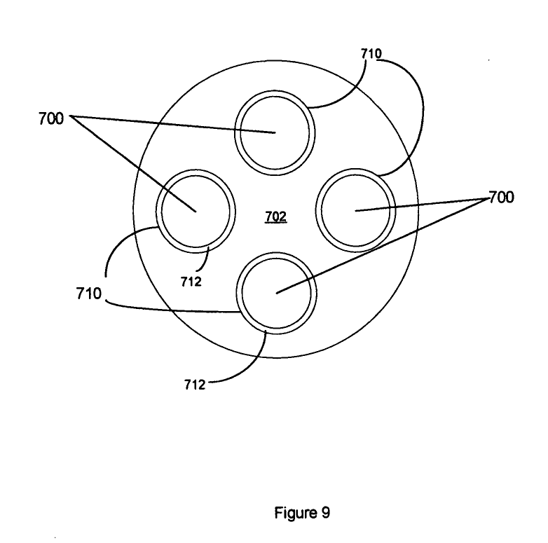

Referring to FIG. 9, a heating element wire 700 is threaded through ceramic tubing 702. As a heating element, the ceramic gets in the way of heat flow. The element wire 700 has to get somewhat hotter; it heats the ceramic 702 which in turn heats the work. Thus, ΔT is made larger. If the difference between ceramic tubing hole size 710 and diameter of wires 700 is also kept minimal, ΔT is kept minimal. Radiation between hot wire and hot ceramic is small because their temperature difference is small. Conductivity through the space 712 around the wire to the ceramic is also small because the space (whether gas or vacuum) has low thermal conductivity. Keeping the space 712 minimal maximizes thermal conductivity and minimizes temperature difference while allowing free thermal expansion as the element and ceramic heat and cool.

8. Feed Wire Orientation

Referring again to FIG. 7, in its simplest form, element wire 700 can be slipped through a single hole ceramic tube 702. But, in that case, incorporating the wire ends into an electrical circuit presents a problem. If the ceramic 702 has two holes, the wire can be looped back so both terminals 704 are on the same end. The two terminals 704 thus can be incorporated into a single terminal end 706 so the heating element assembly is simply plugged into the furnace in cartridge fashion. This further has the advantage of doubling the amount of heat source within the ceramic without the disadvantage of coiling. If the ceramic is round (which is preferred, because the access port 400 it slips through is round), four holes make more complete use of the ceramic available. In that case, it doubles again the amount of heat source within the ceramic without the disadvantage of coiling. Even more than four holes could be considered but the increasing complexity can be undesirable. Furthermore, too much wire crowding interferes with heat flow which means wires start to heat each other, rather than the work, as is the case with coiling. The four hole ceramic heating element shown in FIGS. 7, 8, 9 and 10 thus provides the following advantages:
element wire insulation;
structural support;
free thermal expansion;
material compatibility (alumina);
maximized power density;
minimized ΔT;
better volt/ohm power characteristics;
cartridge insertion (single end terminals);
intercepts element evaporation from contaminating work.

9. Terminal Configuration

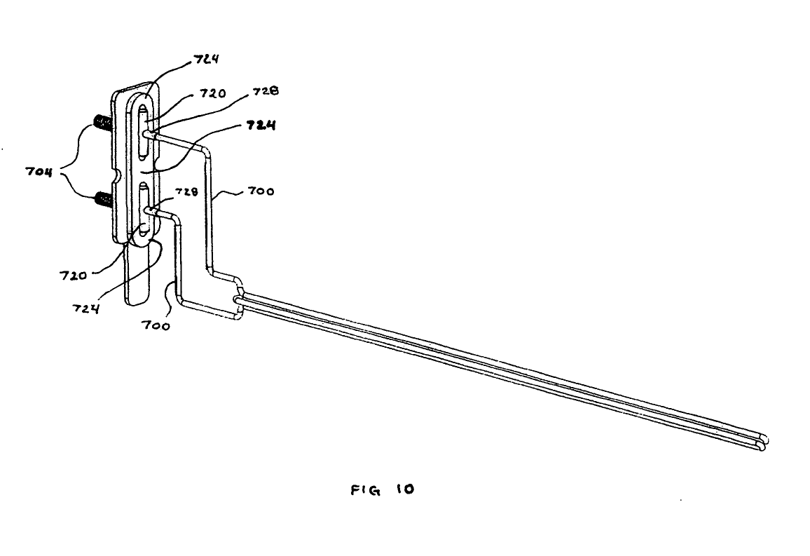

Referring to FIG. 10, the two terminal wires 704 of heating element wires 700 obviously have to remain electrically insulated. But there is no need for heating action in this area, providing wider range for choice of insulator material. Heating in this area risks damage to the terminal's ability to provide and maintain stable electrical connection. It also represents wasted power for the furnace and should be avoided or minimized.

Terminal ends 704 are screw terminals that provide durable secure connections. The preferred embodiment includes a short transverse rod (torque eliminator) 720 on the threaded terminal end 704 which conformably engages a recess provided in insulation material 724. The transverse rod 720 prevents inadvertent torque, during terminal tightening, from causing damage to the heating element wire 700. The same piece of insulation material 724 can serve both terminals, incorporating them in a single unit which facilitates element installation or removal. A preferred insulation material 724 is Teflon. The terminals themselves are secured to the heating elements by welding or brazing at a terminal weld or braze joint 728.

10. Terminal Heat Reduction

Referring to FIG. 8A, the intent of the heating element wire 700 is to generate heat inside the process chamber 102. But the electrical circuit extends outside the process chamber on the far or distal end 802 (to provide support) and on the terminal end 706 (to provide power connections). To maximize percent power generated in the process chamber, the heating element is structured to have as much of the circuit resistance inside the process chamber as possible. Since Kanthal resistivity is high, the Kanthal is located only on that element portion inside the process chamber 102. As shown in FIG. 8B, the Kanthal is also slightly smaller in diameter than the rest of the element wire to further increase its resistance. FIG. 8B shows the relative diameters of the heating element wire 700.

Referring to FIG. 8A, at the distal end, the Kanthal is welded at point 810 to Nichrome (a high temperature alloy but not as high as Kanthal). The Nichrome serves as a transition zone to reduce heating but is not able to eliminate it. Heat is conducted to this area from the hotter Kanthal and through the ceramic insulator (not shown) encasing the wire. Electrical resistive heating also occurs but at a lower level.

The welding of Kanthal, especially to a different material such as Nichrome, is challenging. There is the risk that the weld joint would be a weak spot in the element structure incompatible with the intended high temperature service. Kanthal also tends to get very brittle and fragile after welding. However, welding techniques have been developed which make such structures feasible and practical.

At the terminal end, the Kanthal is also welded to Nichrome at 812. The Nichrome is then welded to nickel at 814 which has much lower electrical resistance but not as much heat resistance. The nickel is then finally welded to the screw terminal 704 itself at terminal weld 728 (FIG. 10). The nickel to Nichrome weld is positioned for support inside the ceramic tubing but most of the nickel is exposed to help remove unwanted heat.

With this configuration, 80% or more of the heating can be generated within the process chamber 102.

The heating element design was completed with the needs of the process chamber in mind. Referring to FIG. 4, the heating portion of these elements consists of one quarter inch (0.250) diameter ceramics which slip into holes in the process chamber which are slightly larger (0.256-0.265). These heating elements 106 can now be placed about three eighths inch (0.375) apart (see FIG. 6). The planar array of heating elements thermodynamically approaches a single continuous sheet of hot surface. If one such sheet is disposed above the work being processed, and a second sheet below, the work is exposed to a good approximation of an isothermal chamber; the work being surrounded by hot (heating element) surface with reflective heat containment beyond that (see FIG. 5, FIG. 6).

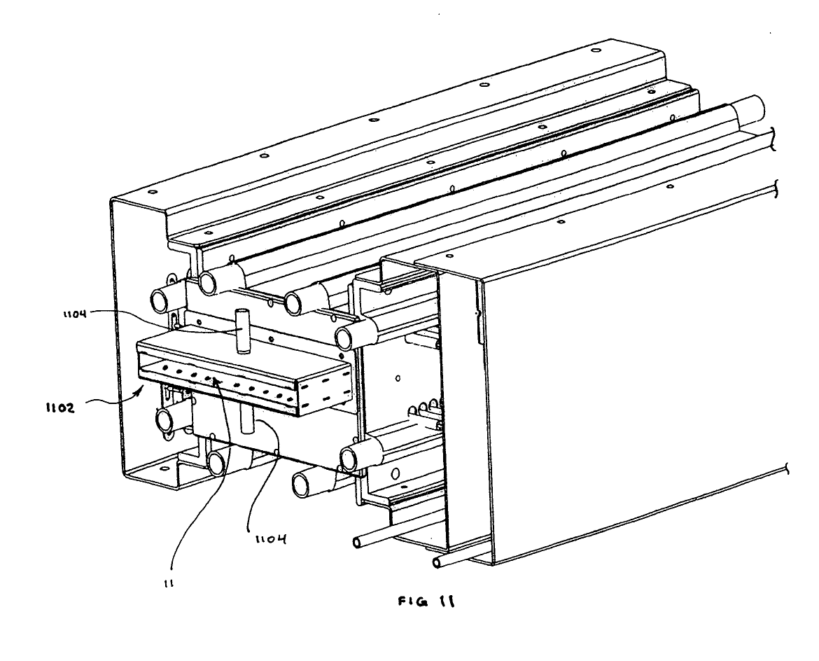

Referring to FIG. 11, for many applications, the atmosphere in the process chamber must be carefully controlled. To do this, the inlet and outlet ends of the process chamber are fitted with gas purge structures 1102 which prevent air from entering but allow work (substrates) to pass through. Inlets or outlets for the gas purge supply are provided at 1104. The purge gas is then diffused through a plurality of diffusers 1108 which are small bores in the bottom and top of the gas purge structure which facilitate the creation of a gas curtain.

Diffusion flow is completely random. In an unsealed enclosure, diffusion is going on into and out of the enclosure at the leak sites. If the enclosure is pressurized so that directed flow out of the leaks occurs, this outward flow competes with diffusion flow. Once the flow induced by pressure exceeds the diffusion flow, outside air cannot get into the enclosure and the enclosure is thus purged.

For the purging of the process chamber enclosure formed by gas purge structures 1102, the velocity at the leaks, due to input flow, is proportional to the square root of the induced pressure (differential, “in” vs. “out”). Comparing liquids and gasses this way is a bit awkward because of gas compressibility, but if the actual pressure differential is small it doesn't have much effect on the result.

If the velocity (V) is in centimeters per second (cm/sec) and the density (d) is in grams per cubic centimeter (g/cm³), the pressure (P) is in dynes per square centimeter (dynes/cm²), an uncommon unit. For small pressure, inches of water (In.H₂O) may be the preferred unit. Accordingly, a pressure, P, of:

$$\begin{matrix}1 dyne \text{/} {cm}^{2} = 4.0148 \times {10}^{- 4} In . {H}_{2} O \\ = 1.4504 \times {10}^{- 5} PSI ( Pounds per Square Inch )\end{matrix}$$

or conversely
1 inch H₂O=2490.82 dynes/cm²=0.036127 PSI If “P” in the above equation is in “In.H₂O”, the equation becomes:

$$V ( cm \text{/} sec ) = \sqrt{\frac{2 P \times 2490.82}{d}} = 70.58 \sqrt{\frac{P}{d}}$$

If the purge gas is argon, its density is:
0.0017837 gm/cm³ (0° C., atmospheric pressure)
0.0013054 gm/cm³ (100° C., atmospheric pressure) The equation becomes:

$$\begin{matrix}V ( cm \text{/} sec ) = 70.58 \sqrt{\frac{P ( In . {H}_{2} O )}{.0013054 gm \text{/} {cm}^{3}}} \\ = 1953.5 \sqrt{P ( In . {H}_{2} O )}\end{matrix}$$

If the process chamber is at temperature of 1000° C. or more, the leak areas are estimated to be of the order of 100° C. (the rationale for using the 100° C. density).

Therefore, if a velocity of 2 inches per second, which equals 5.08 cm/sec, is the purge requirement to overcome diffusion, the associated pressure is:

$$\begin{matrix}5.08 ( cm \text{/} sec ) = 1953.5 \sqrt{P ;} \\ P = \frac{5.08}{1953.5} exponent 2 \\ = 6.76 \times {10}^{- 6} ( In . {H}_{2} O ) \\ = 0.244 \times {10}^{- 6} PSI\end{matrix}$$

(One quarter of one millionth of one PSI)

If the accumulated “leaks” amount to one square inch, (=6.45 cm²) the flow volume is:

$$\begin{matrix}6.45 \times 5.08 = 32.77 {cm}^{3} \text{/} sec \\ = 1966.4 {cm}^{3} \text{/} minute \\ = approx . 2 liters \text{/} min .\end{matrix}$$

The above calculations compare very favorably to an empirical listing (called the Beaufort Scale) used in meteorology, where wind velocity is compared to pressure (force per area) induced on surfaces such as buildings. The Beaufort Scale can thus be described as (for air at 25° C.):

$$\begin{matrix}V ( mph ) = 241.46 \sqrt{P ( PSI )} ; & P ( PSI ) = \frac{{V}^{2} ( mph )}{58302.9} \\ V ( mph ) = 20.12 \sqrt{P ( Lbs \text{/} {Ft}^{2} )} ; & P ( Lbs \text{/} {Ft}^{2} ) \frac{{V}^{2} ( mph )}{404.8}\end{matrix}$$

As set forth above, in accordance with an aspect of the invention, only one quarter of one millionth of one PSI is necessary to form a gas curtain at diffusers 1108 for complete isolation of the process chamber while enabling processing at atmospheric pressure.

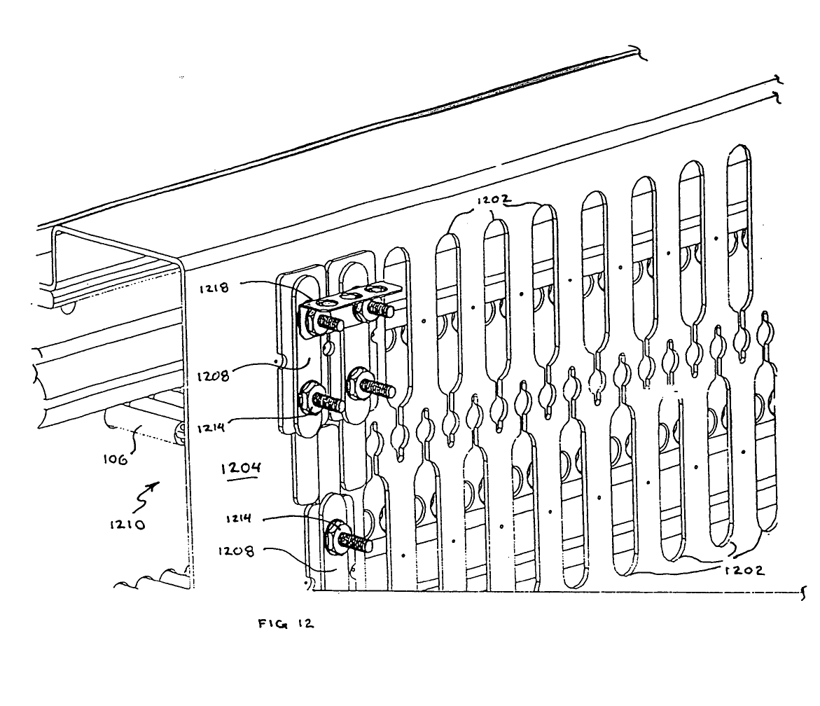

Referring to FIG. 12, the heat element terminal structure is designed so that when a heating element 106 is installed through a terminal access port 1202 in a terminal panel 1204, the terminal 1208 covers the access port 1202. The terminal panel 1204 thus forms a secondary plenum or terminal chamber 1210 along side the process chamber (not shown). The terminal chamber 1210 can now be purged with inert gas (such as argon). This gas can now enter the process chamber itself, through clearance at 400 around the heating element ceramics 106 as shown in FIG. 6.

This arrangement also benefits the heating elements themselves. As mentioned, the Kanthal alloy serves at high temperature by forming a protective surface of aluminum oxide. But this oxide is formed at the expense of the underlying metal. If the element operates in an inert atmosphere, the protective oxide is unnecessary, or, exaggerated thicknesses of oxide don't tend to form. At high service temperature, there is a tendency for thicker oxide to form on Kanthal. But, because the oxide thermal expansion is different than the metal, it spalls off when the element cools and has to reform when reheated. This action is suppressed or eliminated in argon. Such purging action also implies that high temperature, but oxidation sensitive material, like molybdenum, can be considered for heating element service.

The terminal chamber purge, however, would not protect the far end of the heating elements or process chamber leaks around the elements. As mentioned, the elements are disposed in an upper row and lower row. The upper row terminals 1208 are all fastened to the terminal panel 1204 on one side. The lower terminals need a separate panel which is on the other side of the process chamber. Thus, the upper row terminal chamber protects its own terminals, plus the far end of the lower row elements, and vice versa. The element ends, and the process chamber are thus fully protected.

As mentioned, the Kanthal can be benefited by this gas protection. The nickel and Nichrome also benefit.

It is unlikely that the argon purge can remove the unwanted residual heat reaching the terminals. Argon would also be expensive as a cooling gas.

The terminal panel 1204 with elements installed forms an array of exposed electrical contacts which should be covered for safety purposes. This terminal cover (not shown) is thus included in the design concept.

The power connections 1214 to the terminals are designed to include a cooling fin bus bar feature 1218. Under the terminal cover, these cooling fins can be subjected to blowers or air jets as a means of removing unwanted heat.

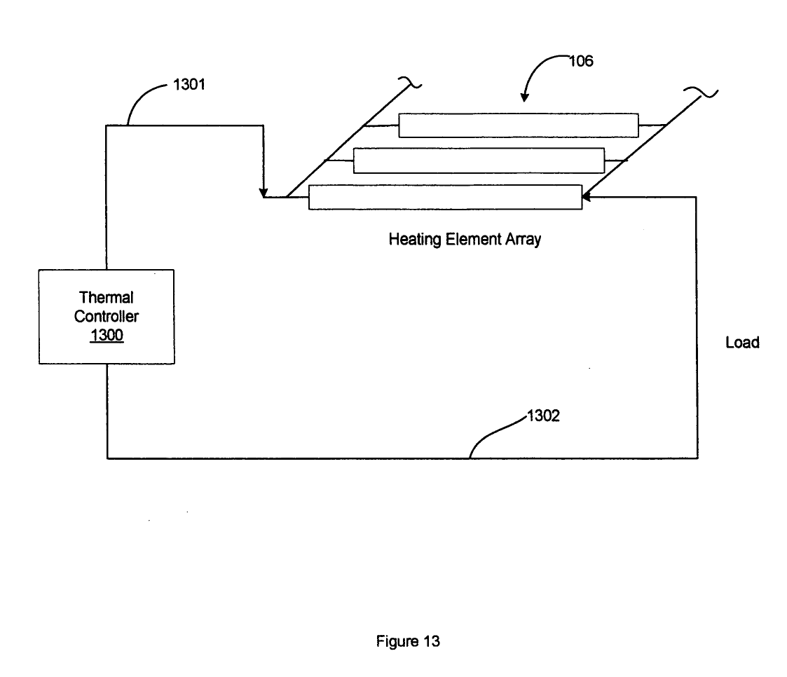

Referring to FIG. 13, the linear configuration of heating elements provides a direct relationship of watts per linear inch. This enables temperature within the ceramic sleeve to be determined directly as a function of resistance. Thermal controller 1300 monitors the electrical resistance of the heating circuit over lead 1301 to determine temperature of the heating elements in accordance with techniques which are well known. The ΔT between heating element temperature and work temperature is minimized for all of the reasons set forth above. Accordingly, the heating element temperature is essentially the work piece temperature. A feedback loop is provided at 1302 to enable the thermal controller 1300 vary the electrical load to increase or decrease temperature.

This aspect of the invention enables accurate measurement and precise control of the work piece temperature to bring the workpiece or substrate to a desired temperature for a corresponding CVD process. In a CVD process, substrate temperature is a critical parameter during each process step. Deposition gases react within particular temperature windows and deposit on the substrate. This aspect of the invention advantageously enables process parameters and materials to be carefully controlled to ensure the high quality of the resulting device layers.

While the invention has been described in connection with what are presently considered to be the most practical and preferred embodiments, it is to be understood that the invention is not limited to the disclosed embodiments and alternatives as set forth above, but on the contrary is intended to cover various modifications and equivalent arrangements included within the scope of the forthcoming claims. For example, other metals, such as molybdenum can be encased in a ceramic sleeve enabling thermal expansion of the metals and providing mechanical support to enable such metals to function as high temperature heating elements. Also, a seam can be provided in the aluminum walls along the line of the access ports for the heating elements. The seam would enable the furnace to be assembled in two halves; and would provide ease of disassembly of the furnace for cleaning and replacement of heating elements

Therefore, persons of ordinary skill in this field are to understand that all such equivalent arrangements and modifications are to be included within the scope of the following claims.

1. An atmospheric pressure chemical vapor deposition furnace for depositing thin films on a workpiece at a temperature of 1200° C. and above comprising:
a process chamber comprising a reflective interior surface for containing and reflecting heat back to heating elements, including means for actively cooling the process chamber surface such that a thermal response of the furnace is determined solely by thermal mass of the heating elements;
a plurality of linear heating elements disposed in one or more planar arrays within the process chamber and in proximity to the workpiece such that temperature difference (DT) between the workpiece and heating elements is minimized and the heating elements, with the reflective heat containment of the process chamber, approximate an isothermal chamber.

2. An atmospheric pressure furnace comprising:
an aluminum process chamber having an exterior surface and polished interior surfaces;
one or more elongated heating elements, extending through apertures in the process chamber to the exterior surface, said heating elements comprising Kanthal resistive wires protected by alumina ceramic tubing, and said resistive wires in each heating element extending longitudinally through the ceramic tubing such that the wires freely expand and contract in response to temperature changes;
cooling channels disposed in the exterior surface of the process chamber; and,
aluminum rails provided on interior surfaces of the process chamber, said rails positioned to slideably transport one or more workpieces from a receiving end of the process chamber to an exit end for continuous processing.

3. An atmospheric pressure furnace comprising:
a process chamber having highly polished interior surfaces defining an entrance, an exit and a processing region for a workpiece;
rails provided on opposed interior surfaces of the process chamber, said rails positioned for supporting a workpiece along an axis of travel from the entrance, through the processing region, and to the exit of the process chamber;
a first array of parallel, closely-spaced, elongated heating elements positioned below the rails;
a second array of parallel, closely-spaced, elongated heating elements positioned above the rails, wherein said first and second arrays of heating elements comprise resistive wires protected by ceramic tubing and the ends of the heating elements extend through apertures in the process chamber and are held in an external mounting structure for connection to an electric current; and
cooling channels disposed in the exterior surface of the process chamber.

4. A process chamber as in claim 3 wherein the process chamber comprises aluminum having highly polished interior surfaces for reflecting heat back to the processing region such that the temperature difference between the heating elements and the workpiece is minimized.

5. A furnace as in claim 3 wherein the polished interior surfaces are plated with gold.

6. A furnace as in claim 3 wherein the rails are made of aluminum.

7. A furnace as in claim 3 wherein the rails are made of molybdenum.

8. A furnace as in claim 3 wherein the resistive wires in each heating element extend longitudinally through the ceramic tubing such that the wires are free to expand and contract in response to temperature changes.

9. A furnace as in claim 3 wherein each heating element is a modular unit adapted for individual replacement without removing other heating elements.

10. A furnace as in claim 3 wherein the electrical connection to each heating element is made via threaded metal terminals incorporating short transverse rods that conformably engage recesses in the mounting structure to prevent inadvertent torque from causing damage to wires of the heating element.

11. A furnace as in claim 3 further comprising gas purge structures at the entrance and exit of the process chamber that prevent air from entering the process chamber while allowing the workpiece to pass through, thus enabling high-throughput processing.

12. A furnace as in claim 3 further comprising a thermal controller that can change the temperature in the process chamber from one temperature to another within a range of 800-1400 C in less than 30 minutes.

13. A furnace as in claim 3 further comprising a thermal controller which can cause the temperature in the process chamber to be cooled from more than about 1200 C to less than 800 C in less than 30 minutes.

14. A furnace comprising:
a process chamber comprising polished aluminum walls; and
one or more heating elements provided inside the chamber in direct proximity to a workpiece, the ends of the heating elements extending through apertures in the aluminum walls for receiving an electric current, such that the temperature of the heating elements and the workpiece exceed the melting temperature of the process chamber for more than 30 minutes during furnace operation.

15. A furnace as in claim 14 further comprising highly polished interior surfaces defining the process chamber for the purpose of reflecting heat upon a workpiece; and
cooling channels conformably disposed in the exterior surfaces of the walls for removing non-reflected heat, such that the reflectivity of the polished interior surfaces does not decrease as the process temperature of the furnace increases.
